(19) United States
(12) Patent Application Publication
(10) Pub. No.: US 2007/0187227 A1
(43) Pub. Date: Aug. 16, 2007

(54) Method for making a perpendicular magnetic recording disk

(76) Inventor: Ernesto E. Marinero, Saratoga, CA (US)

Correspondence Address: THOMAS R. BERTHOLD, 18938 CONGRESS JUNCTION COURT, SARATOGA, CA, 95070, US

(21) Appl. No.: 11/354,505

(22) Filed: Feb. 15, 2006

(51) Int. Cl. C23C 14/00

(52) U.S. Cl. 204/192.2

(57) ABSTRACT

A method for making a perpendicular magnetic recording disk that has a hexagonal-close-packed (hcp) granular cobalt alloy recording layer (RL) containing an additive oxide or oxides grown on an a hcp intermediate layer (IL) involves roughening the surface of the IL. The IL, which is typically hcp Ru or Ru alloy, is deposited at substantially lower sputtering pressure than in the prior art, which results in less of a columnar structure for the IL and a smoother IL surface. The relatively smooth surface of the IL is then modified with ion bombardment, such as by sputter etching in Ar, to provide a “nano-roughed” surface onto which the RL is grown. The roughened surface of the IL promotes the grain segregation in the RL as the RL grows. However, because the IL has less of a columnar structure there are fewer pathways for water and corrosive agents.

### BACKGROUND OF THE INVENTION

1. Field of the Invention

This invention relates generally to perpendicular magnetic recording media, and more particularly to a method for making a perpendicular magnetic recording disk for use in magnetic recording hard disk drives.

2. Description of the Related Art

Perpendicular magnetic recording, wherein the recorded bits are stored in a perpendicular or out-of-plane orientation in the recording layer, is a promising path toward ultra-high recording densities in magnetic recording hard disk drives. A common type of perpendicular magnetic recording system is one that uses a “dual-layer” media. This type of system is shown in FIG. 1 with a single write pole type of recording head. The dual-layer media includes a perpendicular magnetic data recording layer (RL) formed on a “soft” or relatively low-coercivity magnetically permeable underlayer (SUL). The SUL serves as a flux return path for the field from the write pole to the return pole of the recording head. In FIG. 1, the RL is illustrated with perpendicularly recorded or magnetized regions, with adjacent regions having opposite magnetization directions, as represented by the arrows. The magnetic transitions between adjacent oppositely-directed magnetized regions are detectable by the read element or head as the recorded bits.

FIG. 2 is a schematic of a cross-section of a prior art perpendicular magnetic recording disk showing the write field H_{w} acting on the recording layer RL. The disk also includes the hard disk substrate, a seed or onset layer (OL) for growth of the SUL, an intermediate layer (IL) between the SUL and the RL, and a protective overcoat (OC). The IL is a nonmagnetic layer or multilayer structure, also called an “exchange break layer” or EBL, that breaks the magnetic exchange coupling between the magnetically permeable films of the SUL and the RL and facilitates epitaxial growth of the RL. While not shown in FIG. 2, a seed layer (SL) is typically deposited directly on the SUL to facilitate the growth of the IL. As shown in FIG. 2, the RL is located inside the gap of the “apparent” recording head (ARH), which allows for significantly higher write fields compared to longitudinal or in-plane recording. The ARH comprises the write pole (FIG. 1) which is the real write head (RH) above the disk, and an effective secondary write pole (SWP) beneath the RL. The SWP is facilitated by the SUL, which is decoupled from the RL by the IL and by virtue of its high permeability produces a magnetic mirror image of the RH during the write process. This effectively brings the RL into the gap of the ARH and allows for a large write field H_{w} inside the RL.

One type of material for the RL is a granular ferromagnetic cobalt alloy, such as a CoPtCr alloy, with a hexagonal-close-packed (hcp) crystalline structure having the c-axis oriented substantially out-of-plane or perpendicular to the RL. The granular cobalt alloy RL should also have a well-isolated fine-grain structure to produce a high-coercivity (H_{c}) media and to reduce intergranular exchange coupling, which is responsible for high intrinsic media noise. Enhancement of grain segregation in the cobalt alloy RL is achieved by the addition of oxides, including oxides of Si, Ta, Ti, and Nb. These oxides tend to precipitate to the grain boundaries, and together with the elements of the cobalt alloy form nonmagnetic intergranular material. A perpendicular magnetic recording medium with a RL of a CoPtCr granular alloy with added SiO₂ is described by H. Uwazumi, et al., “CoPtCr—SiO₂ Granular Media for High-Density Perpendicular Recording”, IEEE Transactions on Magnetics, Vol. 39, No. 4, July 2003, pp. 1914-1918. A perpendicular magnetic recording medium with a RL of a CoPt granular alloy with added Ta₂O₅ is described by T. Chiba et al., “Structure and magnetic properties of Co—Pt—Ta₂O₅ film for perpendicular magnetic recording media”, Journal of Magnetism and Magnetic Materials, Vol. 287, February 2005, pp. 167-171.

The cobalt alloy RL has substantially out-of-plane or perpendicular magnetic anisotropy as a result of the c-axis of its hcp crystalline structure being induced to grow substantially perpendicular to the plane of the layer during deposition. To induce this growth of the hcp RL, the IL onto which the RL is formed is also an hcp material. Ruthenium (Ru) and certain Ru alloys, such as RuCr, are nonmagnetic hcp materials that are used for the IL.

The enhancement of segregation of the magnetic grains in the RL by the additive oxides is important for achieving high areal density and recording performance. The intergranular material not only effectively decouples intergranular exchange but also exerts control on the size and distribution of the magnetic grains in the RL. Current disk fabrication methods achieve this segregated RL by growing the RL on an IL that exhibits columnar growth of its grains. The columnar growth of the IL is accomplished by sputter depositing it at a relatively high sputtering pressure. However, growth of the RL on this type of IL leads to significant roughness and discontinuities in the RL, and consequently to reduced mechanical integrity of the protective OC. Poor OC coverage, roughness in the RL, and columnar growth of the IL provide a relatively easy path for water and corrosive agents to migrate through these layers and interact with the SUL. Formation of the IL at reduced sputtering pressure can reduce the RL roughness and improve the corrosion resistance of the disk. However, disks with ILs formed at lower sputtering pressure exhibit significantly reduced coercivity and thus poor recording performance.

What is needed is a perpendicular magnetic recording disk that has a granular cobalt alloy RL with additive oxides and that exhibits good corrosion resistance without compromising recording performance.

### SUMMARY OF THE INVENTION

The invention is a method for making a perpendicular magnetic recording disk that has a hcp granular cobalt alloy recording layer (RL) containing an additive oxide or oxides grown on an a hcp intermediate layer (IL). The IL, which is typically hcp Ru or Ru alloy, is deposited at substantially lower sputtering pressure than in the prior art, which results in less of a columnar structure for the IL and a smoother IL surface. The relatively smooth surface of the IL is then modified with ion bombardment to provide a “nano-roughed” surface onto which the RL is grown. The roughened surface of the IL promotes the grain segregation in the RL as the RL grows. However, because the IL has less of a columnar structure there are fewer pathways for water and corrosive agents. The ion bombardment can be by sputter etching in a noble gas atmosphere or in mixtures of noble gases and reactive species (such as Ar/Oxygen, Ar/Hydrogen, Ar/Chlorine, etc.). The equipment for forming the roughed IL surface includes pulsed, mid-frequency or RF cathodes, ion-beam sources, RIE (reactive ion etching), ECR (electron cyclotron resonance) and ICP (inductively coupled plasma) sources, and is located adjacent to the sputtering station used for growth of the IL. Thus there is no impact on process time or vacuum integrity of the process chamber.

For a fuller understanding of the nature and advantages of the present invention, reference should be made to the following detailed description taken together with the accompanying figures.

### BRIEF DESCRIPTION OF THE DRAWINGS

FIG. 1 is a schematic of a prior art perpendicular magnetic recording system.

FIG. 2 is a schematic of a cross-section of a perpendicular magnetic recording disk according to the prior art and depicting the write field.

FIG. 3 is a schematic of a cross-section of a perpendicular magnetic recording disk according to the prior art and illustrating an antiferromagnetically-coupled SUL.

FIG. 4A is a transmission electron microscopy (TEM) image of a portion of a surface of a CoPtCr—SiO₂ RL formed on an IL of a bilayer of Ru.

FIG. 4B is a TEM image of a cross-section of a portion of a disk with a CoPtCr—SiO₂ RL formed on an IL of a bilayer of Ru.

FIG. 5 is a schematic of a cross-section of a perpendicular magnetic recording disk made according to this invention and illustrating an etched surface on the IL for subsequent growth of the RL.

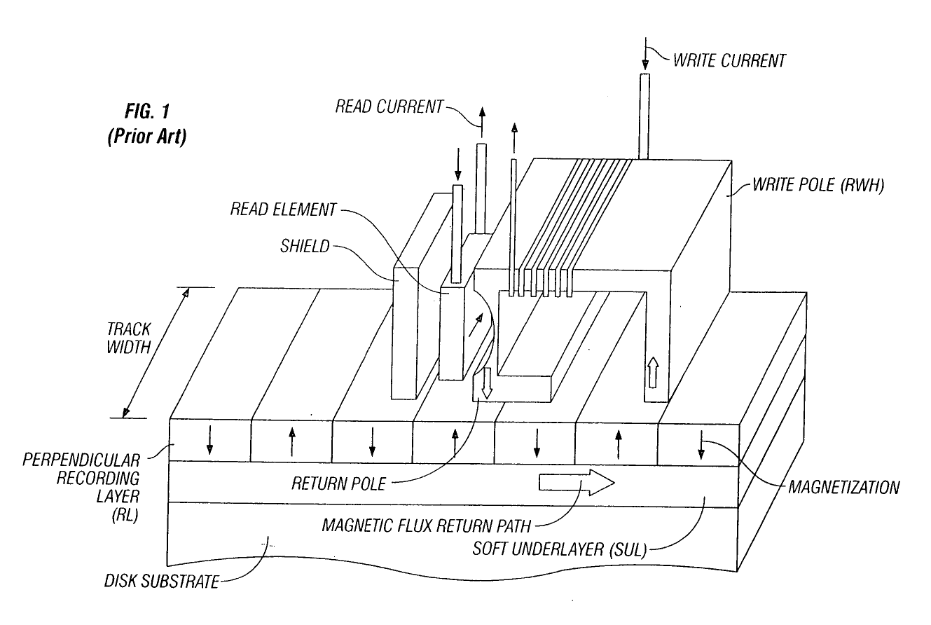

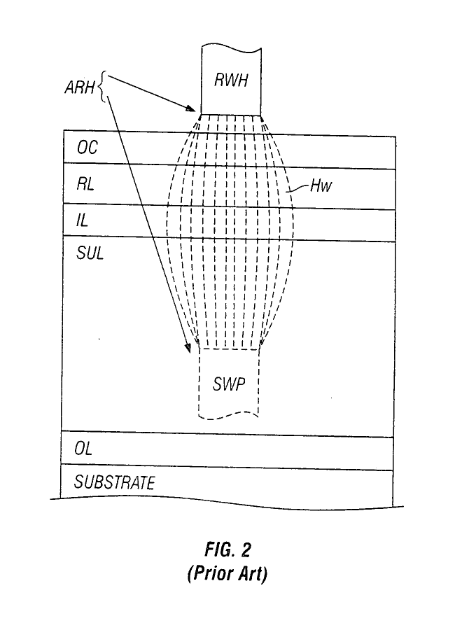

### DETAILED DESCRIPTION OF THE INVENTION

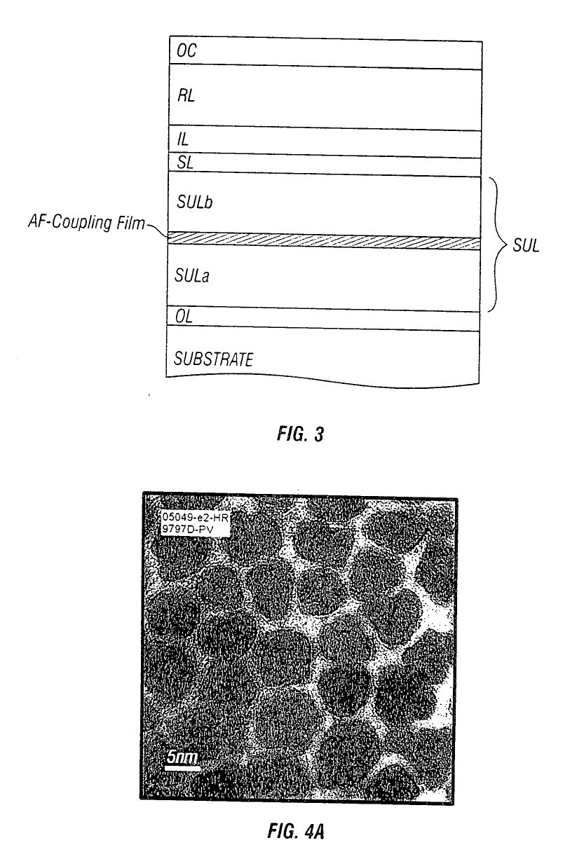

FIG. 3 is a schematic of a cross-section of a perpendicular magnetic recording disk according to the prior art and illustrating an antiferromagnetically-coupled SUL. The various layers making up the disk are located on the hard disk substrate. The substrate may be any commercially available glass substrate, but may also be a conventional aluminum alloy with a NiP or other known surface coating, or an alternative substrate, such as silicon, canasite or silicon-carbide. The SUL is located on the substrate, either directly on the substrate or directly on an adhesion layer or OL. The OL facilitates the growth of the SUL and may be an AlTi alloy or a similar material with a thickness of about 2-5 nanometers (nm). In the disk of FIG. 3, the SUL is a laminated or multilayered SUL formed of multiple soft magnetic layers (SULa and SULb) separated by an interlayer film (such as Ru, Ir, or Cr) that acts as an antiferromagnetic (AF) coupling film to mediate antiferromagnetic exchange coupling between SULa and SULb. This type of SUL is described in U.S. Pat. Nos. 6,686,070 B1 and 6,835,475 B2. However, instead of the AF-coupled SUL, the SUL may be a single-layer SUL or a non-AF-coupled laminated or multilayered SUL that is formed of multiple soft magnetic films separated by nonmagnetic films, such as films of carbon or SiN or electrically conductive films of Al or CoCr. The SUL layer or layers are formed of amorphous magnetically permeable materials such as alloys of CoNiFe, FeCoB, CoCuFe, NiFe, FeAlSi, FeTaN, FeN, FeTaC, CoTaZr, CoFeB, and CoZrNb. The thickness of the SUL is typically in the range of approximately 50-400 nm. The OC formed on the RL may be an amorphous “diamond-like” carbon film or other known protective overcoat, such as silicon nitride (SiN).

The nonmagnetic IL on the SUL is a nonmagnetic metal or alloy having a hexagonal close-packed (hcp) crystal structure for controlling the hcp crystal orientation in the granular RL. The IL promotes the growth of the hcp granular RL so that its c-axis is oriented substantially perpendicular, thereby resulting in perpendicular magnetic anisotropy. Ruthenium (Ru) is a commonly used material for the IL, but other materials include a metal selected from Ti, Re, and Os, and an alloy containing at least one element selected from Ti, Re, Ru, and Os, including Ru-based alloys such as a RuCr alloy. The IL may be formed on a seed layer (SL) formed on the SUL.

The RL is a granular ferromagnetic Co alloy with intergranular material that includes an oxide or oxides. The oxides are typically oxides of one or more of Si, Ta, Ti and Nb. The RL may also contain Cr, with one or more oxides of Cr also being present as intergranular material.

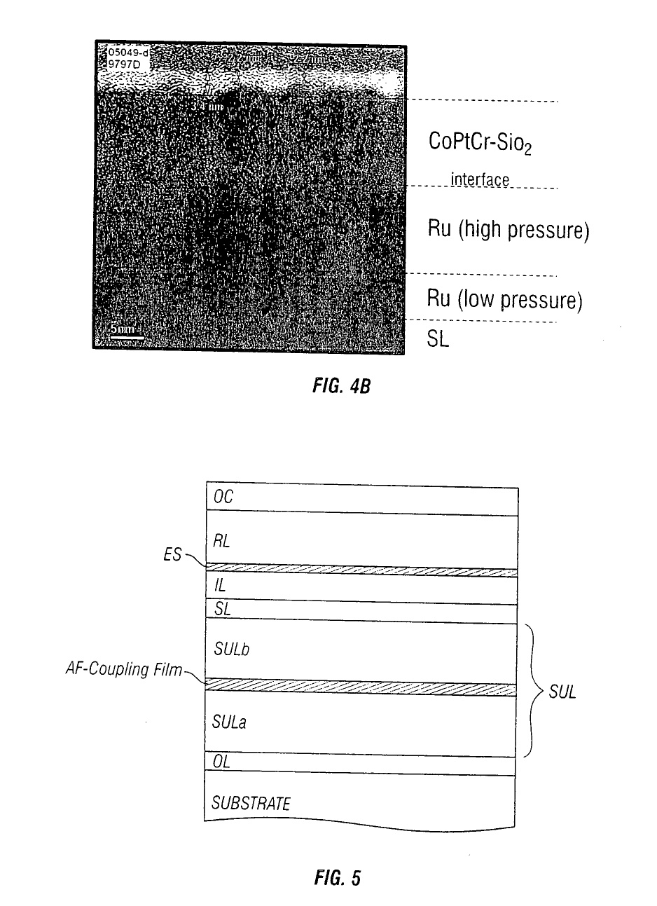

FIG. 4A is a transmission electron microscopy (TEM) image of a portion of the surface of a CoPtCr—SiO₂ RL formed on an IL of a bilayer of Ru. FIG. 4B is a TEM image of a cross-section of a portion of the disk shown in FIG. 4A. FIGS. 4A-4B illustrate the segregated nature of the RL, i.e., the magnetic grains segregated by the intergranular material, which is predominantly SiO₂. To achieve a segregated RL, the oxide-containing RL is deposited onto an IL having the correct lattice parameter, growth orientation and interfacial roughness. Ru and Ru alloys, such as RuCr, grown at relatively high sputtering pressure meet this requirement. The high-pressure growth of the IL provides a relatively roughened template which facilitates the segregation of the RL grains during growth of the RL. In the disk illustrated in FIGS. 4A-4B, the IL was a first Ru layer (5 nm) sputter deposited at relatively low pressure (6 mTorr) followed by a second Ru layer (12 nm) sputter deposited at relatively high pressure (36 mTorr). FIG. 4B shows the relatively rough interface between the second Ru layer and the RL. FIG. 4B also shows a columnar structure with well segregated grains whose columnar growth extends in some cases throughout the full thickness of the Ru bilayer. The columnar growth of the upper Ru layer in the IL drives the segregation of the magnetic grains in the RL. The columnar growth is believed due to the low surface mobility of the sputtered particles which is a result of the loss of kinetic energy due to the high number of collisions experienced in the high pressure sputtering environment. However, the high pressure sputter deposition of the IL can cause adjacent granular columns in the RL to have height variations comparable to the OC thickness, which can cause faults in the OC. The intergranular regions in the RL also exhibit a high density of voids and crystallographic faults which can provide pathways for humidity and corrosive gases to interact with the underlying SUL.

Reducing the sputtering pressure during deposition of the IL is known to improve the corrosion resistance of the disk. For example, for the disk with the dual-layer Ru IL as described above, a reduction of the sputtering pressure during deposition of the upper Ru layer from 46 mTorr to 36 mTorr improved the corrosion resistance of the disk. However, larger reductions in sputtering pressure lead to RLs with unacceptable values for coercivity and nucleation field. To achieve high performance perpendicular magnetic recording disks at ultra-high recording densities, e.g., greater than 200 Gbits/in², the RL should exhibit low intrinsic media noise (high signal-to-noise ratio or SNR), a coercivity H_{c} greater than about 5000 Oe, and a nucleation field Hₙ greater (more negative) than about −1500 Oe. The nucleation field Hₙ has several meanings, but as used herein it is the reversing field, preferably in the second quadrant of the M-H hysteresis loop, at which the magnetization drops to 90% of its saturation value Mₛ. The more negative the nucleation field, the more stable the remanent magnetic state will be because a larger reversing field is required to alter the magnetization. Table 1 shows the values of H_{c} and Hₙ for disks with a CoPtCr—SiO₂ RL and a 16 nm thick IL of Ru₇₅Cr₂₅, where the subscripts refer to atomic percent (at. %), deposited at different sputtering pressures.

TABLE 1

| Sputtering Pressure | | |
|---|---|---|
| (mTorr) | H_{c} (Oe) | Hₙ (Oe) |
| 46 | 6612 | −2093 |
| 9.7 | 3737 | −1316 |
| 4.0 | 2747 | −847 |

Table 1 shows that as the sputtering pressure for the IL is reduced, significant losses in H_{c} and Hₙ are observed. This is believed to be due to changes in interface morphology such as a reduction in roughness at the IL-RL interface, and less columnar growth of the IL, which hinder the desired segregation of the RL grains and thus the development of high H_{c} and Hₙ.

The perpendicular magnetic recording disk made according to the method of the present invention is illustrated in FIG. 5. The structure is similar to the prior art structure of FIG. 3 but includes an etched surface (ES) on the IL onto which the RL is subsequently grown. The IL is deposited at relatively low sputtering pressure (less than about 12 mTorr). Thus the IL exhibits less of a columnar structure. The entire IL, or the topmost layer if the IL is a bilayer, has a structure shown by the lower Ru layer in FIG. 4B, so there are fewer pathways for corrosive gases. Also, the less columnar growth of the IL results in less inducing of roughness in the RL and OC, which can also reduce the susceptibility to corrosion. The ES controls the segregation of the RL magnetic grains without negatively impacting the RL's epitaxial growth, which is needed to orient the c-axis of the RL out-of-plane.

The ES formed by the method of this invention generates the required interfacial roughness with a high degree of spatial resolution. It also suppresses large scale asperities in the IL that can arise during sputter deposition from random fluctuations in grain growth kinetics. These asperities are typically removed during a later burnishing step as part of the post-sputter processing of the disk. However, the mechanical removal of the asperities can generate voids or breaks in the thin films of the disk, thereby providing a path for the diffusion of corrosive gases into the disk. With the method of this invention the number of asperities can be reduced and the overall flatness of the RL improved.

In the method of this invention, the following layers are first grown in sequence: an adhesion layer or OL (such as AlTi) on a rigid substrate (such as glass or a Al—Mg alloy) followed by growth of the SUL, preferably an antiferromagnetically-coupled SUL, then the SL or ALs and finally the hcp IL (such as Ru or RuX alloys, such as RuCr). The IL may be a bilayer like that shown in FIG. 4B. The IL, or the upper portion of the IL if it is a bilayer, is grown under high mobility conditions employing a relatively low sputtering pressure (less than about 12 mTorr) and a growth rate conducive to the formation of a dense, relatively smooth surface.

After the IL has been sputter deposited at relatively low pressure to provide a relatively smooth surface, the ES is formed on the IL to generate a “nano-roughed” interface for growth of the RL. An in-situ IL surface modification step is introduced which bombards the topmost layer of the hcp IL with ions and/or neutral species. Examples of such surface-modifying exposures include sputter-etching in a pure noble gas atmosphere, and sputter-etching in mixtures of noble gases and reactive species (such as Ar/Oxygen, Ar/Hydrogen, Ar/Chlorine, etc.). The equipment for forming the ES includes pulsed, mid-frequency or RF cathodes, ion-beam sources, RIE (reactive ion etching), ECR (electron cyclotron resonance) and ICP (inductively coupled plasma) sources. The equipment to perform the IL surface modification is located adjacent to the sputtering station used for growth of the IL. Thus there is no impact on process time or vacuum integrity of the process chamber. After forming the ES the RL is deposited on the IL, followed by deposition of the OC on the RL.

The modification of surfaces by interaction with ions is a well-studied phenomenon and is widely employed in the electronic and optical industries. The amount of energy imparted to a surface is readily controlled by varying the kinetic energy of the bombarded ions. The chemical and physical processes that are induced in the surface by ion impact are also controlled by this kinetic energy. Unique surface topologies can be generated by controlling the energy and exposure dose of the surface.

In a study by Thiele et al., “Grain Size Control in FePt Thin Films by Ar—Ion Etched Pt Seed Layers”, IEEE Transactions on Magnetics, Vol. 37, No. 4, July 2001, pp. 1271-1273, Pt seed layers were sputter etched ex situ in a DC ion beam system. The ion beam was operated at an Ar gas pressure of 10⁻² mbar and a power of 600 W, resulting in Ar-ion energies of about 200 eV. The Ar-ion etching resulted in a significant nano-roughening of the Pt seed layer, with the RMS roughness increasing from about 0.7 nm before sputter etching to about 4.5 nm after sputter etching.

Matsunuma et al, “Perpendicular magnetic recording media based on Co—Pd multilayer with granular seed layer”, IEEE Transactions on Magnetics, Vol. 38, No. 4, July 2002, pp. 1622-1626, investigated the effect of sputter-etching the surface of an amorphous FeTaC underlayer prior to depositing a Pd—SiN seed layer onto which a Co/Pd multilayer was grown. The FeTaC underlayer was in-situ plasma etched in an Ar atmosphere. The microstructure of the Co/Pd multilayer grown on the etched surface exhibited well-separated columns with clear grain boundaries, whereas no obvious grain boundaries were observed for the Co/d multilayer grown on the non-etched underlayer.

The amount of roughness desired for the IL surface can be estimated based on known properties of the disk OC. For a given OC thickness and material, there exists a maximum roughness value beyond which the OC mechanical properties are compromised. The roughness can be determined from atomic force microscopy (AFM) measurements. For a carbon OC of 4 nm thickness, the peak-peak surface roughness should not exceed about 3.0 nm. For a SiN OC of 4 nm thickness, the peak-peak surface roughness should not exceed about 3.5 nm.

The method of the present invention can be any ion surface modification process that uses equipment that can be easily incorporated into the disk manufacturing tool and that has the resolution to produce the desired nano-roughness of the IL surface. An important requirement is the control of the ion energy to exert the desired surface modification within the time restrictions of the manufacturing process flow. The desired ion energy will range from about 50 to 500 eV. RF and DC magnetron sources are compatible with the sputtering pressure regime of disk manufacturing.

In addition to sputter etching with noble gas ions, such as Ar and Ar plasma etching, ICP and ECR are methods that are favored for their high etching rates. For example, Park et al, “Inductively Coupled Plasma Etching of Ta, Co, Fe, NiFe, NiFeCo, and MnNi with Cl₂/Ar Discharges”, Korean J. Chem. Eng., 21(6), 1235-1239 (2004) used ICP etching with Cl₂/Ar plasma mixtures to modify the surface of sputter-deposited thin films of NiFeCo. The ion energy during the etching step in these experiments was controlled by varying the RF power. The surface roughness of the etched samples was relatively constant at RF power up to 200 W, but a rougher surface at a higher RF power was obtained.

The experiments in the above-described references illustrate how ion bombardment of a thin film surface can be modified to vary its surface roughness. Thus in the preset invention the IL can be deposited at relatively low sputtering pressure, less than about 12 mTorr, and the surface then modified by ion bombardment. The oxide-containing RL is then deposited on the nano-roughened IL surface, which facilitates the grain segregation of the RL as the RL grows. The RL is typically deposited at a higher sputtering pressure, i.e., greater than 16 mTorr. The recording properties are improved if the RL is deposited a sputtering pressure significantly higher than the sputtering pressure for the IL and at a relatively slow deposition or growth rate. The optimal values of coercivity for the RL are achieved for sputtering pressures between about 30 and 60 mTorr.

While the present invention has been particularly shown and described with reference to the preferred embodiments, it will be understood by those skilled in the art that various changes in form and detail may be made without departing from the spirit and scope of the invention. Accordingly, the disclosed invention is to be considered merely as illustrative and limited in scope only as specified in the appended claims.

What is claimed is:

1. A method for making a perpendicular magnetic recording medium comprising:
providing a substrate;
sputter depositing an intermediate layer on the substrate at a first sputtering pressure;
bombarding the surface of the intermediate layer with ions; and
sputter depositing a magnetic recording layer on the surface of the intermediate layer at a sputtering pressure substantially higher than the sputtering pressure for the deposition of the intermediate layer.

2. The method of claim 1 wherein bombarding the surface of the intermediate layer with ions comprises sputter etching the surface of the intermediate layer in a noble gas atmosphere.

3. The method of claim 2 wherein the noble gas atmosphere includes reactive species selected from the group consisting of oxygen, hydrogen and chlorine.

4. The method of claim 2 wherein sputter etching comprises sputter etching in an Ar atmosphere.

5. The method of claim 1 wherein bombarding the surface of the intermediate layer with ions comprises using an inductively coupled plasma source.

6. The method of claim 1 wherein bombarding the surface of the intermediate layer with ions comprises using an electron cyclotron resonance source.

7. The method of claim 1 wherein sputter depositing the intermediate layer comprises sputter depositing an intermediate layer containing Ru, and wherein sputter depositing the recording layer comprises sputter depositing a recording layer comprising a granular ferromagnetic Co alloy and one or more oxides of one or more of Si, Ta, Ti and Nb.

8. The method of claim 7 wherein sputter depositing the intermediate layer comprises sputter depositing the Ru-containing intermediate layer at a sputtering pressure less than about 12 mTorr, and sputter depositing the recording layer on the surface of the intermediate layer comprises sputter depositing the oxide-containing Co alloy recording layer at a sputtering pressure greater than about 30 mTorr.

9. A method for making a perpendicular magnetic recording disk having a substrate; an underlayer of magnetically permeable material on the substrate; a nonmagnetic intermediate layer comprising Ru on the underlayer; and a perpendicular magnetic recording layer comprising a granular ferromagnetic Co alloy and one or more oxides of one or more of Si, Ta, Ti and Nb; the method comprising:
sputter depositing the intermediate layer at a sputtering pressure less than about 12 mTorr;
bombarding the surface of the intermediate layer with ions to roughen the surface; and
sputter depositing the recording layer on the roughened surface of the intermediate layer at a sputtering pressure greater than about 30 mTorr.

10. The method of claim 9 wherein bombarding the surface of the intermediate layer with ions comprises sputter etching the surface of the intermediate layer in a noble gas atmosphere.

11. The method of claim 10 wherein the noble gas atmosphere includes reactive species selected from the group consisting of oxygen, hydrogen and chlorine.

12. The method of claim 9 wherein sputter etching comprises sputter etching in an Ar atmosphere.

13. The method of claim 9 wherein the intermediate layer comprises an alloy comprising Ru and Cr.

14. The method of claim 9 wherein the intermediate layer comprises first and second Ru-containing layers and wherein sputter depositing the intermediate layer comprises sputter depositing the second Ru-containing layer on the first Ru-containing layer at a sputtering pressure less than about 12 mTorr.
